(19) United States
(12) Patent Application Publication
(10) Pub. No.: US 2006/0033217 A1
(43) Pub. Date: Feb. 16, 2006

(54) Flip-chips on flex substrates, flip-chip and wire-bonded chip stacks, and methods of assembling same

(76) Inventors: Brian Taggart, Phoenix, AZ (US); Robert Nickerson, Chandler, AZ (US); Ronald L. Spreitzer, Phoenix, AZ (US)

Correspondence Address: SCHWEGMAN, LUNDBERG, WOESSNER & KLUTH, 1600 TCF TOWER, 121 SOUTH EIGHT STREET, MINNEAPOLIS, MN, 55402, US

(21) Appl. No.: 10/915,293

(22) Filed: Aug. 10, 2004

(51) Int. Cl. H01L 21/48; H01L 23/52

(52) U.S. Cl. 257/778; 438/108; 257/777; 257/688; 438/117

(57) ABSTRACT

A flip-chip is mounted on a flex substrate. A flip-chip is mounted on a flex substrate, and a wire-bond chip is mounted on the flip-chip. A packaged flip-chip die is coupled to the flex substrate. A computing system is also disclosed that includes the flip-chip on a flex substrate configuration.

### TECHNICAL FIELD

Disclosed embodiments relate to flip-chip and wire-bond technology for a substrate. More particularly, disclosed embodiments relate to a flip-chip that is disposed on a flex substrate.

### BACKGROUND INFORMATION

A wire-bonding package usually requires significant routing of traces within a printed circuit board (PCB). The advent of the flexible (flex) substrate, led to several possibilities for wire bonding. The advent of wireless technologies has led to a push to miniaturize packaged integrated circuits such that conventional wire bonding has become a hindrance.

### BRIEF DESCRIPTION OF THE DRAWINGS

In order to understand the manner in which embodiments are obtained, a more particular description of various embodiments briefly described above will be rendered by reference to the appended drawings. Understanding that these drawings depict only typical embodiments that are not necessarily drawn to scale and are not therefore to be considered limiting in scope, some embodiments will be described and explained with additional specificity and detail through the use of the accompanying drawings in which:

FIG. 1 is a side cross-section of a flip-chip on a single-layer flex mounting substrate according to an embodiment;

FIG. 2 is a side cross-section of a flip-chip on a multi-layer flex mounting substrate according to an embodiment;

FIG. 3 is a side cross-section of a flip-chip on a single-layer folded flex mounting substrate that includes a bump according to an embodiment;

FIG. 4 is a side cross-section of a flip-chip on a multi-layer folded flex mounting substrate that includes a bump according to an embodiment;

FIG. 5 is a side cross-section of a flip-chip first die on a multi-layer flex mounting substrate, and a second die above the first die according to an embodiment;

FIG. 6 is a side cross-section of a flip-chip first die on a multi-layer, folded flex mounting substrate, and a second die above the first die according to an embodiment;

FIG. 7 is a side cross-section of a flip-chip first die on a multi-layer flex mounting substrate, and a flip-chip second die above the first die according to an embodiment;

FIG. 8 is a side cross-section of a flip-chip first die on a multi-layer flex mounting substrate, a second die above the first die, and a flip-chip third die above the second die according to an embodiment;

FIG. 9 is a side cross-section of a flip-chip first die on a multi-layer flex mounting substrate, a second die above the first die, and a plurality of flip-chip third dice above the second die according to an embodiment;

FIG. 10 is a side cross-section of a flip-chip first die on a multi-layer flex mounting substrate, a flip-chip second die above the first die, and a plurality of flip-chip third dice above the second die according to an embodiment;

FIG. 11 is a side cross-section of a flip-chip first die on a multi-layer flex mounting substrate, and a wire-bond second die above the first die according to an embodiment;

FIG. 12 is a side cross-section of a flip-chip first die on a multi-layer flex mounting substrate, a wire-bond second die above the first die, and a wire-bond third die above the second die according to an embodiment;

FIG. 13 is a process flow diagram according to various embodiments; and

FIG. 14 is a depiction of a computing system according to an embodiment.

### DETAILED DESCRIPTION

The following description includes terms, such as upper, lower, first, second, etc. that are used for descriptive purposes only and are not to be construed as limiting. The embodiments of a device or article described herein can be manufactured, used, or shipped in a number of positions and orientations. The terms “die” and “processor” generally refer to the physical object that is the basic workpiece that is transformed by various process operations into the desired integrated circuit device. A board is typically a resin-impregnated fiberglass structure that acts as a mounting substrate for the die. A board can be prepared with a bond pad that is flush with the board, or the bond pad can be set upon the board surface. As depicted in this disclosure, a bond pad is not limited to being flush or being set upon the surface only because it is illustrated as such, unless it is explicitly stated in the text. A die is usually singulated from a wafer, and wafers may be made of semiconducting, non-semiconducting, or combinations of semiconducting and non-semiconducting materials.

Reference will now be made to the drawings wherein like structures will be provided with like reference designations. In order to show the structure and process embodiments most clearly, the drawings included herein are diagrammatic representations of embodiments. Thus, the actual appearance of the fabricated structures, for example in a photomicrograph, may appear different while still incorporating the essential structures of embodiments. Moreover, the drawings show only the structures necessary to understand the embodiments. Additional structures known in the art have not been included to maintain the clarity of the drawings.

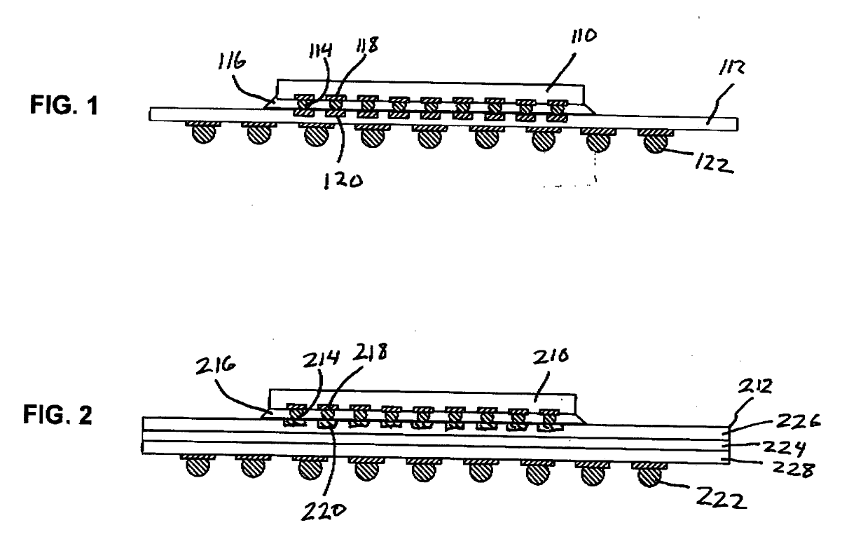

FIG. 1 is a side cross-section of a flip-chip first die 110 on a planar, single-layer flex mounting substrate 112 according to an embodiment. The first die 110 is mounted upon the single-layer flex mounting substrate 112 through a series of first bumps, one of which is designated with the reference numeral 114 according to an embodiment. In an embodiment, the series of bumps 114 is protected by an underfill material 116. The first die 110 is depicted as coupled to the single-layer flex mounting substrate 112 through a plurality of die bond pads, one of which is designated with the reference numeral 118. Coupling of the first die 110 to the single-layer flex mounting substrate 112 is completed through the first bumps 114 and into the single-layer flex mounting substrate 112 with a plurality of board bond pads, one of which is designated with the reference numeral 120. In an embodiment, the single-layer flex mounting substrate 112 is bumped with a plurality of second bumps, one of which is designated with the reference numeral 122. The second bumps 122 are useful for coupling the die to a board such as a motherboard or the like.

FIG. 2 is a side cross-section of a flip-chip first die 210 on a multi-layer flex (MLF) mounting substrate 212 according to an embodiment. The first die 210 is mounted upon the MLF mounting substrate 212 through a series of first bumps, one of which is designated with the reference numeral 214 according to an embodiment. In an embodiment, the series of bumps 214 is protected by an underfill material 216. The first die 210 is depicted as coupled to the MLF mounting substrate 212 through a plurality of die bond pads, one of which is designated with the reference numeral 218. Coupling of the first die 210 to the MLF mounting substrate 212 is completed through the first bumps 214 and into the MLF mounting substrate 212 with a plurality of board bond pads, one of which is designated with the reference numeral 220. In an embodiment, the MLF mounting substrate 212 is bumped with a plurality of second bumps, one of which is designated with the reference numeral 222. The second bumps 222 are useful for coupling the die to a board such as a motherboard or the like.

The MLF mounting substrate 212 includes a core 224, an upper layer 226, and a lower layer 228. In an embodiment, electrical communication through the MLF mounting substrate 212 is carried out according to conventional technique.

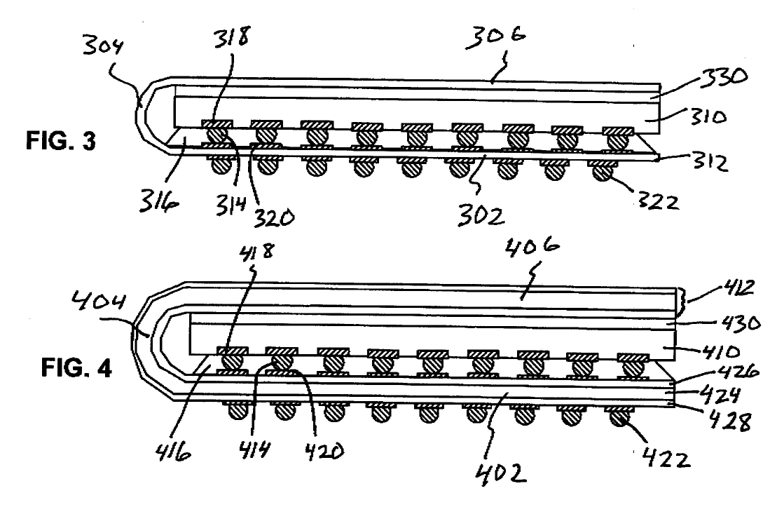

FIG. 3 is a side cross-section of a flip-chip first die 310 on a single-layer folded flex mounting substrate 312 that includes a bump according to an embodiment. The single-layer folded flex mounting substrate 312 also includes a die-level section 302, a fold section 304, and an above-die section 306.

The first die 310 is mounted upon the single-layer folded flex mounting substrate 312 through a series of first bumps, one of which is designated with the reference numeral 314 according to an embodiment. In an embodiment, the series of bumps 314 is protected by an underfill material 316. The first die 310 is depicted as coupled to the single-layer folded flex mounting substrate 312 through a plurality of die bond pads, one of which is designated with the reference numeral 318. Coupling of the first die 310 to the single-layer folded flex mounting substrate 312 is completed through the first bumps 314 and into the single-layer folded flex mounting substrate 312 with a plurality of board bond pads, one of which is designated with the reference numeral 320.

In an embodiment, the single-layer folded flex mounting substrate 312 is bumped with a plurality of second bumps, one of which is designated with the reference numeral 322. The second bumps 322 are useful for coupling the die to a board such as a motherboard or the like.

In an embodiment, the above-die section 306 of the single-layer folded flex mounting substrate 312 is held in place by a first adhesive layer 330 that attaches the first die 310 to the above-die section 306.

FIG. 4 is a side cross-section of a flip-chip first die 410 on a multi-layer folded flex (MFF) mounting substrate 412 according to an embodiment. The MFF mounting substrate 412 also includes a die-level section 402, a fold section 404, and an above-die section 406.

The first die 410 is mounted upon the MFF mounting substrate 412 through a series of first bumps, one of which is designated with the reference numeral 414 according to an embodiment. In an embodiment, the series of bumps 414 is protected by an underfill material 416. The first die 410 is depicted as coupled to the MFF mounting substrate 412 through a plurality of die bond pads, one of which is designated with the reference numeral 418. Coupling of the first die 410 to the MFF mounting substrate 412 is completed through the first bumps 414 and into the MFF mounting substrate 412 with a plurality of board bond pads, one of which is designated with the reference numeral 420. In an embodiment, the MFF mounting substrate 412 is bumped with a plurality of second bumps, one of which is designated with the reference numeral 422. The second bumps 422 are useful for coupling the die to a board such as a motherboard or the like.

The MFF mounting substrate 412 includes a core 424, an upper layer 426, and a lower layer 428. In an embodiment, electrical communication through the MFF mounting substrate 412 is carried out according to conventional technique.

In an embodiment, the above-die section 406 of the MFF mounting substrate 412 is held in place by a first adhesive layer 430 that attaches the first die 410 to the above-die section 406.

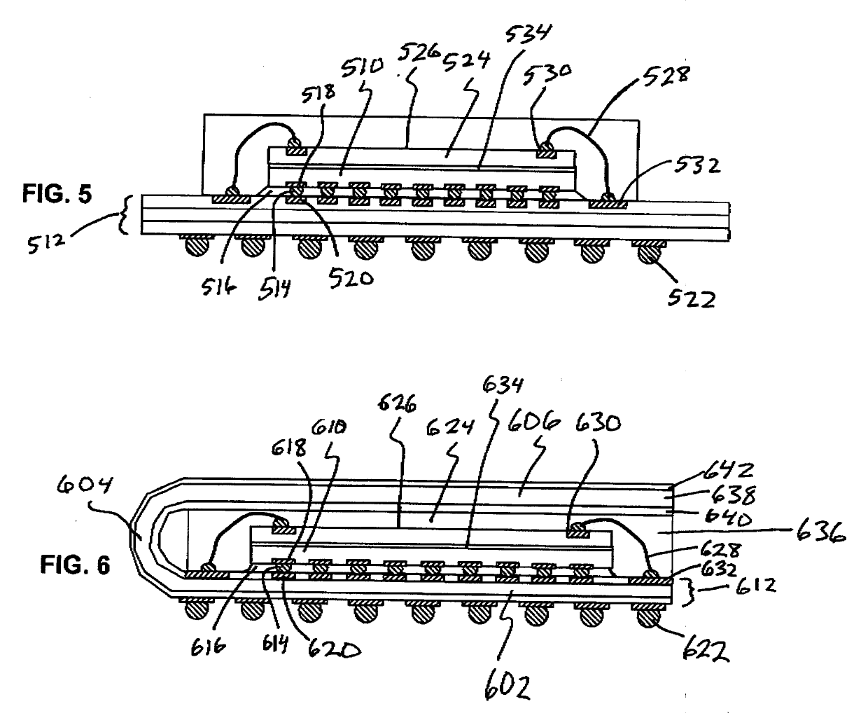

FIG. 5 is a side cross-section of a flip-chip first die 510 on a mounting substrate 512, and a second die 524 above the first die 510 according to an embodiment. In an embodiment, the mounting substrate is a rigid mounting substrate. In an embodiment, the mounting substrate is a MLF mounting substrate. Hereinafter the mounting substrate will be referred to as an MLF mounting substrate, but it can also be a rigid mounting substrate. The first die 510 is mounted upon the MLF mounting substrate 512 through a series of first bumps, one of which is designated with the reference numeral 514 according to an embodiment. In an embodiment, the series of first bumps 514 is protected by an underfill material 516. The first die 510 is depicted as coupled to the MLF mounting substrate 512 through a plurality of first die bond pads, one of which is designated with the reference numeral 518. Coupling of the first die 510 to the MLF mounting substrate 512 is completed through the first bumps 514 and into the MLF mounting substrate 512 with a plurality of board first bond pads, one of which is designated with the reference numeral 520. In an embodiment, the MLF mounting substrate 512 is bumped with a plurality of second bumps, one of which is designated with the reference numeral 522. The second bumps 522 are useful for coupling the die to a board such as a motherboard or the like.

The second die 524 is depicted mounted upon the first die 510. The second die 524 includes an active surface 526, which is oriented upwardly, and a backside surface, which is mounted against the first die 510. Electrical coupling of the second die 524 to the MLF mounting substrate 512 is done with a bond wire 528. The bond wire 528 couples a second die bond pad 530 to a flex substrate wire-bond pad 532.

In an embodiment, the second die 524 is adhered to the first die 510 by an adhesive 534. In an embodiment, the adhesive is a thermal grease. In an embodiment, the adhesive is a thermal plastic material. In an embodiment, the adhesive is a metal such as a tin alloy.

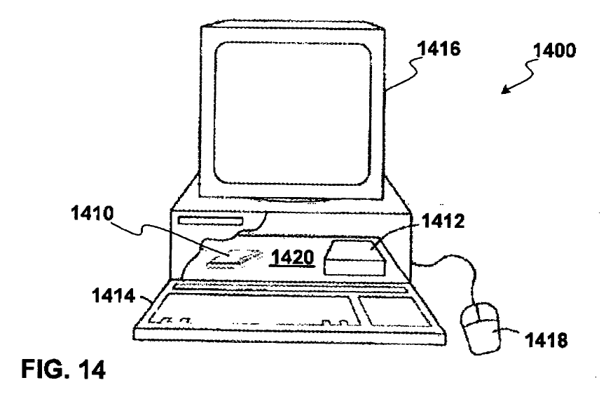

FIG. 5 also depicts electrical coupling capability of the second die 524 to a larger substrate, through the second bumps 522. In an embodiment, the larger substrate, e.g., the board 1420 in FIG. 14, is a motherboard, a mezzanine board, an expansion card, or others. In an embodiment, the larger substrate is a penultimate casing for a wireless handheld device such as a wireless telephone.

In an embodiment, a process of wirebonding includes reverse wire bonding. The process includes first attaching the bond wire 528 at the flex substrate wire-bond pad 532, followed by second attaching the bond wire 528 at the second die bond pad 530. In an embodiment, a process of wirebonding includes forward wire bonding. The process includes first attaching the bond wire 528 at the second die bond pad 530, followed by second attaching the bond wire 528 at the flex substrate wire-bond pad 532. After wire bonding, the first and second dice are encapsulated with a mold cap material 536.

FIG. 6 is a side cross-section of a flip-chip first die 610 on an MFF mounting substrate 612, and a second die 624 above the first die 610 according to an embodiment. The multi-layer folded flex mounting substrate 612 also includes a die-level section 602, a fold section 604, and an above-die section 606. The structure of the multi-layer folded flex substrate includes a substrate core 638, an upper layer 640, and a lower layer 642.

The first die 610 is mounted upon the MFF mounting substrate 612 through a series of first bumps, one of which is designated with the reference numeral 614 according to an embodiment. In an embodiment, the series of first bumps 614 is protected by an underfill material 616. The first die 610 is depicted as coupled to the MFF mounting substrate 612 through a plurality of first die bond pads, one of which is designated with the reference numeral 618. Coupling of the first die 610 to the MFF mounting substrate 612 is completed through the first bumps 614 and into the MFF mounting substrate 612 with a plurality of board first bond pads, one of which is designated with the reference numeral 620. In an embodiment, the multi-layer folded flex mounting substrate 612 is bumped with a plurality of second bumps, one of which is designated with the reference numeral 622. The second bumps 622 are useful for coupling the die to a board such as a motherboard or the like.

The second die 624 is depicted mounted upon the first die 610. The second die 624 includes an active surface 626, which is oriented upwardly, and a backside surface, which is mounted against the first die 610. Electrical coupling of the second die 624 to the MFF mounting substrate 612 is done with a bond wire 628. The bond wire 628 couples a second die bond pad 630 to a flex substrate wire-bond pad 632.

In an embodiment, the second die 624 is adhered to the first die 610 by an adhesive 634. In an embodiment, the adhesive is a thermal grease. In an embodiment, the adhesive is a thermal plastic material. In an embodiment, the adhesive is a metal such as a tin alloy.

FIG. 6 also depicts electrical coupling capability of the second die 624 to a larger substrate, through the second bumps 622. In an embodiment, the larger substrate, e.g., the board 1420 in FIG. 14, is a motherboard, a mezzanine board, an expansion card, or others. In an embodiment, the larger substrate is a penultimate casing for a wireless handheld such as a wireless telephone.

In an embodiment, a process of wirebonding includes reverse wire bonding. The process includes first attaching the bond wire 628 at the flex substrate wire-bond pad 632, followed by second attaching the bond wire 628 at the second die bond pad 630. In an embodiment, a process of wirebonding includes forward wire bonding. The process includes first attaching the bond wire 628 at the second die bond pad 630, followed by second attaching the bond wire 628 at the flex substrate wire-bond pad 632. After wire bonding, the first and second dice are encapsulated with a mold cap material 636.

In an embodiment, after formation of the mold cap material 636, the multi-layer folded flex mounting substrate 612 is secured with a flex adhesive (not pictured), such that the upper layer 640 is adhered, face down, onto the mold cap material 636.

FIG. 7 is a side cross-section of a flip-chip first die 710 on an MFF mounting substrate 712 according to an embodiment. The MFF mounting substrate 712 also includes a lower die-level section 702, a fold section 704, and an upper die-level section 706. The structure of the MFF substrate 712 includes a substrate core 738, an upper layer 740, and a lower layer 742.

The first die 710 is mounted upon the MFF mounting substrate 712 through a series of first bumps, one of which is designated with the reference numeral 714 according to an embodiment. In an embodiment, the series of first bumps 714 is protected by a first underfill material 716. The first die 710 is depicted as coupled to the MFF mounting substrate 712 through a plurality of die bond pads, one of which is designated with the reference numeral 718. Coupling of the first die 710 to the MFF mounting substrate 712 is completed through the first bumps 714 and into the MFF mounting substrate 712 with a plurality of board bond pads, one of which is designated with the reference numeral 720. In an embodiment, the MFF mounting substrate 712 is bumped with a plurality of second bumps, one of which is designated with the reference numeral 722. The second bumps 722 are useful for coupling the die to a board such as a motherboard or the like.

In an embodiment, the upper die-level section 706 of the MFF mounting substrate 712 is held in place by a first adhesive layer 730 that attaches the first die 710 to the upper die-level section 706.

The second die 724 is depicted mounted upon the upper die-level section 706, and specifically onto the lower layer 742 as it has been folded to be exposed upwardly. The second die 724 includes an active surface 726, which is oriented downwardly, and a backside surface, which is exposed upwardly.

Electrical coupling of the second die 724 to the MFF mounting substrate 712 is done through a series of third bumps, one of which is designated with the reference numeral 744 according to an embodiment. In an embodiment, the series of third bumps 744 is protected by a second underfill material 746. The second die 724 is depicted as coupled to the MFF mounting substrate 712 through a plurality of second die bond pads, one of which is designated with the reference numeral 748. Coupling of the second die 724 to the MFF mounting substrate 712 is completed through the third bumps 744 and into the multi-layer flex mounting substrate 712 with a plurality of second bond pads, one of which is designated with the reference numeral 750.

FIG. 7 also depicts electrical coupling capability of the second die 724 to a larger substrate, through the third bumps 744. In an embodiment, the larger substrate, e.g., the board 1420 in FIG. 14, is a motherboard, a mezzanine board, an expansion card, or others. In an embodiment, the larger substrate is a penultimate casing for a wireless handheld such as a wireless telephone.

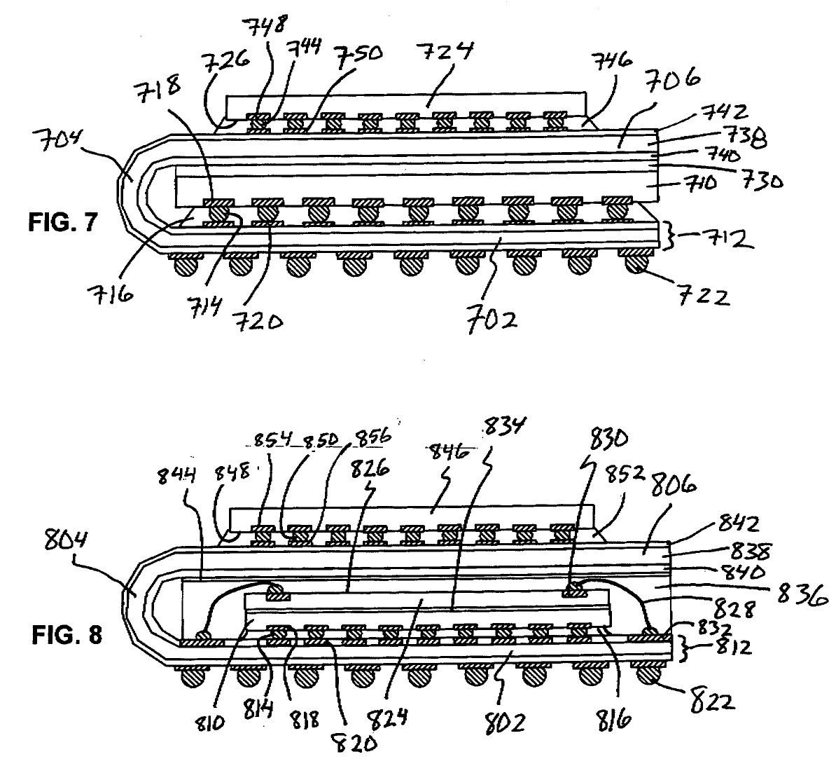

FIG. 8 is a side cross-section of a flip-chip first die 810 on an MFF mounting substrate 812, a second die 824 above the first die, and a flip-chip third die 846 above the second die 824 according to an embodiment. The MFF mounting substrate 812 also includes a die-level section 802, a fold section 804, and an above-die section 806. The structure of the MFF mounting substrate includes 812 a substrate core 838, an upper layer 840, and a lower layer 842.

The first die 810 is mounted upon the MFF mounting substrate 812 through a series of first bumps, one of which is designated with the reference numeral 814 according to an embodiment. In an embodiment, the series of first bumps 814 is protected by a first underfill material 816. The first die 810 is depicted as coupled to the MFF mounting substrate 812 through a plurality of first die bond pads, one of which is designated with the reference numeral 818. Coupling of the first die 810 to the MFF mounting substrate 812 is completed through the first bumps 814 and into the MFF mounting substrate 812 with a plurality of board first bond pads, one of which is designated with the reference numeral 820. In an embodiment, the MFF mounting substrate 812 is bumped with a plurality of second bumps, one of which is designated with the reference numeral 822. The second bumps 822 are useful for coupling the die to a board such as a motherboard or the like.

The second die 824 is depicted mounted upon the first die 810. The second die 824 includes an active surface 826, which is oriented upwardly, and a backside surface, which is mounted against the first die 810. Electrical coupling of the second die 824 to the MFF mounting substrate 812 is done with a bond wire 828. The bond wire 828 couples a second die bond pad 830 to a flex substrate wire-bond pad 832.

In an embodiment, the second die 824 is adhered to the first die 810 by an adhesive 834. In an embodiment, the adhesive is a thermal grease. In an embodiment, the adhesive is a thermal plastic material. In an embodiment, the adhesive is a metal such as a tin alloy.

FIG. 8 also depicts electrical coupling capability of the second die 824 to a larger substrate, through the second bumps 822. In an embodiment, the larger substrate, e.g., the board 1420 in FIG. 14, is a motherboard, a mezzanine board, an expansion card, or others. In an embodiment, the larger substrate is a penultimate casing for a wireless handheld such as a wireless telephone.

In an embodiment, a process of wirebonding includes reverse wire bonding. The process includes first attaching the bond wire 828 at the flex substrate wire-bond pad 832, followed by second attaching the bond wire 828 at the second die bond pad 830. In an embodiment, a process of wirebonding includes forward wire bonding. The process includes first attaching the bond wire 828 at the second die bond pad 830, followed by second attaching the bond wire 828 at the flex substrate wire-bond pad 832. After wire bonding, the first and second dice are encapsulated with a mold cap material 836.

After formation of the mold cap material 836, the MFF mounting substrate 812 is secured with a flex adhesive 844, such that the upper layer 840 is adhered, face down, onto the flex adhesive 844.

In an embodiment, the third die 846 is depicted mounted upon the above-die section 806, and specifically onto the lower layer 842 as it has been folded to be exposed upwardly. The third die 846 includes an active surface 848, which is oriented downwardly, and a backside surface, which is also exposed upwardly.

Electrical coupling of the third die 846 to the MFF mounting substrate 812 is done through a series of third bumps, one of which is designated with the reference numeral 850 according to an embodiment. In an embodiment, the series of third bumps 850 is protected by a third underfill material 852. The third die 846 is depicted as coupled to the MFF mounting substrate 812 through a plurality of third die bond pads, one of which is designated with the reference numeral 854. Coupling of the third die 846 to the MFF mounting substrate 812 is completed through the third bumps 850 and into the multi-layer flex mounting substrate 812 with a plurality of third bond pads, one of which is designated with the reference numeral 856.

FIG. 8 also depicts electrical coupling capability of the third die 846 to a larger substrate, through the third bumps 850 and the second bumps 822 through traces (not pictured) that pass through the fold section 804. In an embodiment, the larger substrate, e.g., the board 1420 in FIG. 14, is a motherboard, a mezzanine board, an expansion card, or others. In an embodiment, the larger substrate is a penultimate casing for a wireless handheld device such as a wireless telephone.

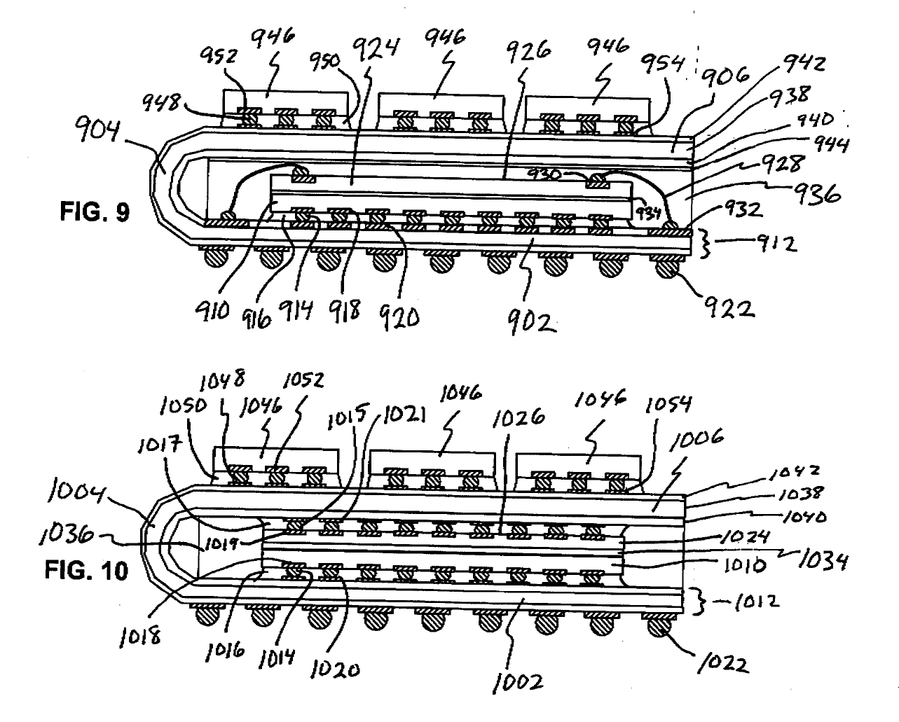

FIG. 9 is a side cross-section of a flip-chip first die 910 on a multi-layer, folded flex (MFF) mounting substrate 912, a second die 924 above the first die 910, and a plurality of flip-chip third dice 946 above the second die 924 according to an embodiment. The MFF mounting substrate 912 also includes a first die-level section 902, a fold section 904, and an upper-die section 906. The structure of the MFF mounting substrate 912 includes a substrate core 938, an upper layer 940, and a lower layer 942.

The first die 910 is mounted upon the MFF mounting substrate 912 through a series of first bumps, one of which is designated with the reference numeral 914 according to an embodiment. In an embodiment, the series of first bumps 914 is protected by first underfill material 916. The first die 910 is depicted as coupled to the MFF mounting substrate 912 through a plurality of first die bond pads, one of which is designated with the reference numeral 918. Coupling of the first die 910 to the MFF mounting substrate 912 is completed through the first bumps 914 and into the MFF mounting substrate 912 with a plurality of board first bond pads, one of which is designated with the reference numeral 920. In an embodiment, the MFF mounting substrate 912 is bumped with a plurality of second bumps, one of which is designated with the reference numeral 922. The second bumps 922 are useful for coupling the die to a board such as a motherboard or the like.

The second die 924 is depicted mounted upon the first die 910. The second die 924 includes an active surface 926, which is oriented upwardly, and a backside surface, which is mounted against the first die 910. Electrical coupling of the second die 924 to the MFF mounting substrate 912 is done with a bond wire 928. The bond wire 928 couples a second die bond pad 930 to a flex substrate wire-bond pad 932.

In an embodiment, the second die 924 is adhered to the first die 910 by a first adhesive 934. In an embodiment, the first adhesive 934 is a thermal grease. In an embodiment, the first adhesive is a thermal plastic material. In an embodiment, the first adhesive is a metal such as a tin alloy.

FIG. 9 also depicts electrical coupling capability of the second die 924 to a larger substrate, through the second bumps 922. In an embodiment, the larger substrate, e.g., the board 1420 in FIG. 14, is a motherboard, a mezzanine board, an expansion card, or others. In an embodiment, the larger substrate is a penultimate casing for a wireless handheld device such as a wireless telephone.

In an embodiment, a process of wirebonding includes reverse wire bonding. The process includes first attaching the bond wire 928 at the flex substrate wire-bond pad 932, followed by second attaching the bond wire 928 at the second die bond pad 930. In an embodiment, a process of wirebonding includes forward wire bonding. The process includes first attaching the bond wire 928 at the second die bond pad 930, followed by second attaching the bond wire 928 at the flex substrate wire-bond pad 932. After wire bonding, the first and second dice are encapsulated with a mold cap material 936.

After formation of the mold cap material 936, the MFF mounting substrate 912 is secured with a flex second adhesive 944, such that the upper layer 940 is adhered, face down, onto the flex second adhesive 944.

In an embodiment, a plurality of third dice 946 is depicted mounted upon the upper die section 906, and specifically onto the lower layer 942 as it has been folded to be exposed upwardly. Each die in the plurality of third dice 946 includes an active surface 948, which is oriented downwardly, and a backside surface, which is also exposed upwardly.

In an embodiment, the second die 924 is absent, but the plurality of third dice 946 is present. In such an embodiment, the third die 946 may be referred to as “a plurality of second dice”.

Electrical coupling of each of the plurality of third dice 946 to the MFF mounting substrate 912 is done through a series of third bumps, one of which is designated with the reference numeral 950 according to an embodiment. In an embodiment, the series of third bumps 950 is protected by a third underfill material 952. Each of the plurality of third dice 946 is depicted as coupled to the MFF mounting substrate 912 through a plurality of third die bond pads, one of which is designated with the reference numeral 954. Coupling of each of the plurality of third dice 946 to the MFF mounting substrate 912 is completed through the third bumps 950 and into the MFF mounting substrate 912 with a plurality of third bond pads, one of which is designated with the reference numeral 954.

In an embodiment, each die of the plurality of third dice 946 is a substantially identical microelectronic device such as a plurality of dynamic random-access memory (DRAM) chips. In an embodiment, at least two of the dice in the plurality of third dice 946 are different such as complementary chips in a chipset. In an embodiment at least three of the dice in the plurality of third dice 946 are different such as complementary chips in a chipset. In an embodiment, none of the dice in the plurality of third dice 946 are the same microelectronic device.

FIG. 9 also depicts electrical coupling capability of the plurality of third dice 946 to a larger substrate, through the third bumps 950 and the second bumps 922 through traces (not pictured) that pass through the fold section 904. In an embodiment, the larger substrate, e.g., the board 1420 in FIG. 14, is a motherboard, a mezzanine board, an expansion card, or others. In an embodiment, the larger substrate is a penultimate casing for a handheld device such as a wireless telephone.

FIG. 10 is a side cross-section of a flip-chip first die 1010 on an MFF mounting substrate 1012, a flip-chip second die 1024 above the first die 1010, and a plurality of flip-chip third dice 1046 above the flip-chip second die 1024 according to an embodiment. The MFF mounting substrate 1012 also includes a first die-level section 1002, a fold section 1004, and an upper-die section 1006. The structure of the MFF mounting substrate 1012 includes a substrate core 1038, an upper layer 1040, and a lower layer 1042.

The flip-chip first die 1010 is mounted upon the MFF mounting substrate 1012 through a series of first bumps, one of which is designated with the reference numeral 1014 according to an embodiment. In an embodiment, the series of first bumps 1014 is protected by an underfill material 1016. The flip-chip first die 1010 is depicted as coupled to the MFF mounting substrate 1012 through a plurality of first die bond pads, one of which is designated with the reference numeral 1018. Coupling of the flip-chip first die 1010 to the MFF mounting substrate 1012 is completed through the first bumps 1014 and into the MFF mounting substrate 1012 with a plurality of board first bond pads, one of which is designated with the reference numeral 1020.

In an embodiment, the MFF mounting substrate 1012 is bumped with a plurality of second bumps, one of which is designated with the reference numeral 1022. The second bumps 1022 are useful for coupling the die to a board such as a motherboard or the like.

The flip-chip second die 1024 is depicted mounted upon the flip-chip first die 1010. The flip-chip second die 1024 includes an active surface 1026, which is oriented upwardly, and a backside surface, which is mounted against the back surface of the flip-chip first die 1010. The flip-chip second die 1024 is mounted upon the MFF mounting substrate 1012 through a series of die second bumps, one of which is designated with the reference numeral 1015 according to an embodiment. In an embodiment, the series of die second bumps 1015 is protected by an underfill material 1017. The flip-chip second die 1024 is depicted as coupled to the MFF mounting substrate 1012 through a plurality of second die bond pads, one of which is designated with the reference numeral 1019. Coupling of the flip-chip second die 1024 to the MFF mounting substrate 1012 is completed through the die second bumps 1015 and into the MFF mounting substrate 1012 with a plurality of board second bond pads, one of which is designated with the reference numeral 1021.

In an embodiment, assembly of the flip-chip first die 1010 and the flip-chip second die 1024 is accomplished by a pick-and place procedure, followed by bump reflow and by folding the MFF mounting substrate 1012 at the fold section 1004. By folding the MFF mounting substrate 1012 at the fold section 1004, the structure achieves a back-to-back, stacked-die configuration.

In an embodiment, the flip-chip second die 1024 is adhered to the flip-chip first die 1010 by a first adhesive 1034. In an embodiment, the first adhesive is a thermal grease. In an embodiment, the first adhesive is a thermal plastic material. In an embodiment, the first adhesive 1034 is a metal such as a tin alloy.

After wire bonding, the first die 1010 and the second die 1024 are encapsulated with a mold cap material 1036.

In an embodiment, the plurality of third dice 1046 is depicted mounted upon the die-above-die section 1006, and specifically onto the lower layer 1042 as it has been folded to be exposed upwardly. Each die in the plurality of third dice 1046 includes an active surface 1048, which is oriented downwardly, and a backside surface, which is exposed upwardly.

Electrical coupling of each of the plurality of third dice 1046 to the MFF mounting substrate 1012 is done through a series of die third bumps, one of which is designated with the reference numeral 1050 according to an embodiment. In an embodiment, the series of die third bumps 1050 is protected by a third underfill material 1052. Each of the plurality of third dice 1046 is depicted as coupled to the MFF mounting substrate 1012 through a plurality of die third bond pads, one of which is designated with the reference numeral 1054. Coupling of each of the plurality of third dice 1046 to the MFF mounting substrate 1012 is completed through the die third bumps 1050 and into the MFF mounting substrate 1012 with a plurality of board third bond pads, one of which is designated with the reference numeral 1056.

In an embodiment, each die of the plurality of third dice 1046 is a substantially identical microelectronic device such as a plurality of dynamic random-access memory (DRAM) chips. In an embodiment, at least two of the dice in the plurality of third dice 1046 are different such as complementary chips in a chipset. In an embodiment at least three of the dice in the plurality of third dice 1046 are different such as complementary chips in a chipset. In an embodiment, none of the dice in the plurality of third dice 1046 are the same microelectronic device.

FIG. 10 also depicts electrical coupling capability of the plurality of third dice 1046 to a larger substrate, through the die third bumps 1050 and the second bumps 1022 through traces (not pictured) that pass through the fold section 1004. In an embodiment, the larger substrate, e.g., the board 1420 in FIG. 14, is a motherboard, a mezzanine board, an expansion card, or others. In an embodiment, the larger substrate is a penultimate casing for a handheld device such as a wireless telephone.

FIG. 11 is a side cross-section of a flip-chip first die 1110 and a second die 1132 disposed on various surfaces of an MFF mounting substrate 1112 according to an embodiment. The MFF mounting substrate 1112 also includes a die-level section 1102, a fold section 1104, and an above-die section 1106.

The first die 1110 is mounted upon the MFF mounting substrate 1112 through a series of first bumps, one of which is designated with the reference numeral 1114 according to an embodiment. In an embodiment, the series of first bumps 1114 is protected by an underfill material 1116. The first die 1110 is depicted as coupled to the MFF mounting substrate 1112 through a plurality of die bond pads, one of which is designated with the reference numeral 1118. Coupling of the first die 1110 to the MFF mounting substrate 1112 is completed through the first bumps 1114 and into the MFF mounting substrate 1112 with a plurality of board bond pads, one of which is designated with the reference numeral 1120. In an embodiment, the MFF mounting substrate 1112 is bumped with a plurality of second bumps, one of which is designated with the reference numeral 1122. The second bumps 1122 are useful for coupling the die to a board such as a motherboard or the like.

The MFF mounting substrate 1112 includes a core 1124, an upper layer 1126, and a lower layer 1128. In an embodiment, electrical communication through the MFF mounting substrate 1112 is carried out according to conventional technique.

In an embodiment, the above-die section 1106 of the MFF mounting substrate 1112 is held in place by a first adhesive layer 1130 that attaches the first die 1110 to the above-die section 1106.

FIG. 11 also depicts the second die 1132 mounted upon the above-die section 1106 of the MFF mounting substrate 1112, and specifically onto the lower layer 1142 as it has been folded to be exposed upwardly. The second die 1132 includes an active surface 1134, which is oriented upwardly, and a backside surface, which is oriented downwardly. In this configuration, the second die 1132 is disposed above the first die 1110.

Electrical coupling of the second die 1132 to the MFF mounting substrate 1112 is done through a plurality of bond wires, one of which is designated with the reference numeral 1136 according to an embodiment. The bond wire 1136 couples a second die bond pad 1138 to a flex substrate wire-bond pad 1140.

FIG. 11 also depicts electrical coupling capability of the second die 1132 to a larger substrate, through the second bumps 1122. In an embodiment, the larger substrate, e.g., the board 1420 in FIG. 14, is a motherboard, a mezzanine board, an expansion card, or others. In an embodiment, the larger substrate is a penultimate casing for a handheld device such as a wireless telephone.

In an embodiment, a process of wirebonding includes reverse wire bonding. The process includes first attaching the bond wire 1136 at the flex substrate wire-bond pad 1140, followed by second attaching the bond wire 1136 at the second die bond pad 1138. In an embodiment, a process of wirebonding includes forward wire bonding. The process includes first attaching the bond wire 1136 at the second die bond pad 1138, followed by second attaching the bond wire 1136 at the flex substrate wire-bond pad 1140. After wire bonding, the first and second dice are encapsulated with a mold cap material 1142.

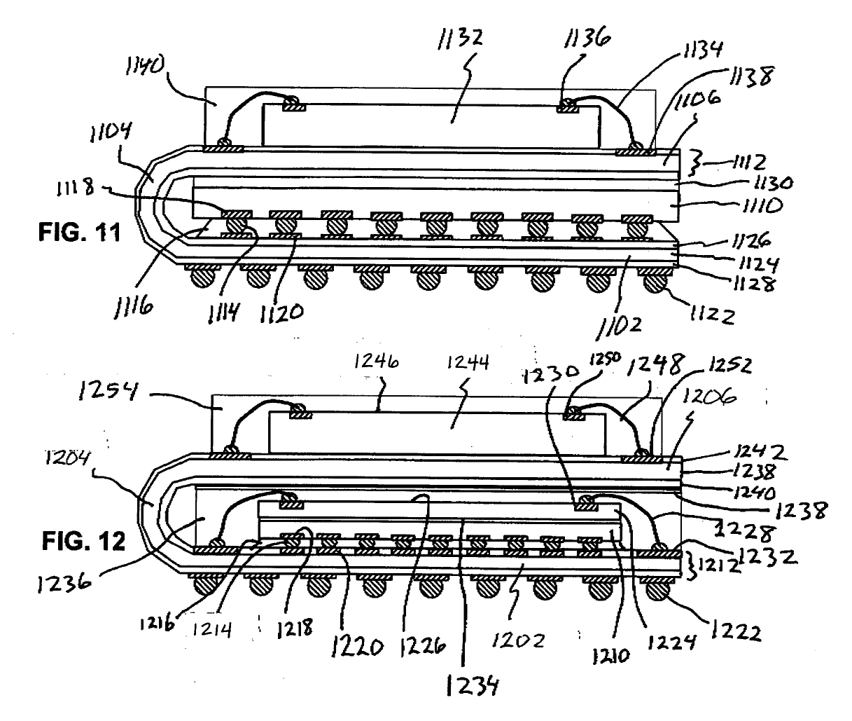

FIG. 12 is a side cross-section of a flip-chip first die 1210 on a multi-layer folded flex mounting substrate 1212, a wire-bond second die 1224 above the first die 1210, and a wire-bond third die 1246 above the second die 1224 according to an embodiment.

The MFF mounting substrate 1212 also includes a die-level section 1202, a fold section 1204, and an above-die section 1206. The structure of the MFF mounting substrate includes 1212 a substrate core 1238, an upper layer 1240, and a lower layer 1242.

The first die 1210 is mounted upon the MFF mounting substrate 1212 through a series of first bumps, one of which is designated with the reference numeral 1214 according to an embodiment. In an embodiment, the series of first bumps 1214 is protected by an underfill material 1216. The first die 1210 is depicted as coupled to the MFF mounting substrate 1212 through a plurality of first die bond pads, one of which is designated with the reference numeral 1218. Coupling of the first die 1210 to the MFF mounting substrate 1212 is completed through the first bumps 1214 and into the MFF mounting substrate 1212 with a plurality of board first bond pads, one of which is designated with the reference numeral 1220. In an embodiment, the MFF mounting substrate 1212 is bumped with a plurality of second bumps, one of which is designated with the reference numeral 1222. The second bumps 1222 are useful for coupling the dice to a board such as a motherboard or the like.

The second die 1224 is depicted mounted upon the first die 1210. The second die 1224 includes an active surface 1226, which is oriented upwardly, and a backside surface, which is mounted against the first die 1210. Electrical coupling of the second die 1224 to the MFF mounting substrate 1212 is done with a first bond wire 1228. The first bond wire 1228 couples a second die bond pad 1230 to a flex substrate wire-bond pad 1232.

In an embodiment, the second die 1224 is adhered to the first die 1210 by an adhesive 1234. In an embodiment, the adhesive is a thermal grease. In an embodiment, the adhesive is a thermal plastic material. In an embodiment, the adhesive is a metal such as a tin alloy.

FIG. 12 also depicts electrical coupling capability of the second die 1224 to a larger substrate, through the second bumps 1222. In an embodiment, the larger substrate, e.g., the board 1420 in FIG. 14, is a motherboard, a mezzanine board, an expansion card, or others. In an embodiment, the larger substrate is a penultimate casing for a handheld device such as a wireless telephone.

In an embodiment, a process of wirebonding includes reverse wire bonding. The process includes first attaching the first bond wire 1228 at the flex substrate wire-bond pad 1232, followed by second attaching the first bond wire 1228 at the second die bond pad 1230. In an embodiment, a process of wirebonding includes forward wire bonding. The process includes first attaching the first bond wire 1228 at the second die bond pad 1230, followed by second attaching the first bond wire 1228 at the flex substrate wire-bond pad 1232. After wire bonding, the first and second dice are encapsulated with a mold cap material 1236.

After formation of the mold cap material 1236, the MFF mounting substrate 1212 is secured with a flex adhesive 1238, such that the upper layer 1240 at the above-die section 1206 is adhered, face down, onto the flex adhesive 1238.

FIG. 12 also depicts the third die 1246 mounted upon the above-die section 1206 of the MFF mounting substrate 1212, and specifically onto the lower layer 1242 as it has been folded to be exposed upwardly. The third die 1246 includes an active surface 1248, which is oriented upwardly, and a backside surface, which is oriented downwardly. In this configuration, the third die 1246 is disposed above both the first die 1210 and the second die 1224.

Electrical coupling of the third die 1246 to the MFF mounting substrate 1212 is done through a plurality of bond wires, one of which is designated with the reference numeral 1250 according to an embodiment. The bond wire 1250 couples a third die bond pad 1252 to a flex substrate wire-bond pad 1254.

FIG. 12 also depicts electrical coupling capability of the third die 1246 to a larger substrate, through the second bumps 1222. In an embodiment, a process of wirebonding includes reverse wire bonding. The process includes first attaching the bond wire 1250 at the flex substrate wire-bond pad 1254, followed by second attaching the bond wire 1250 at the third die bond pad 1252. In an embodiment, a process of wirebonding includes forward wire bonding. The process includes first attaching the bond wire 1250 at the third die bond pad 1252, followed by second attaching the bond wire 1250 at the flex substrate wire-bond pad 1254. After second wire bonding, the third die 1246 is encapsulated with a second mold cap material 1256.

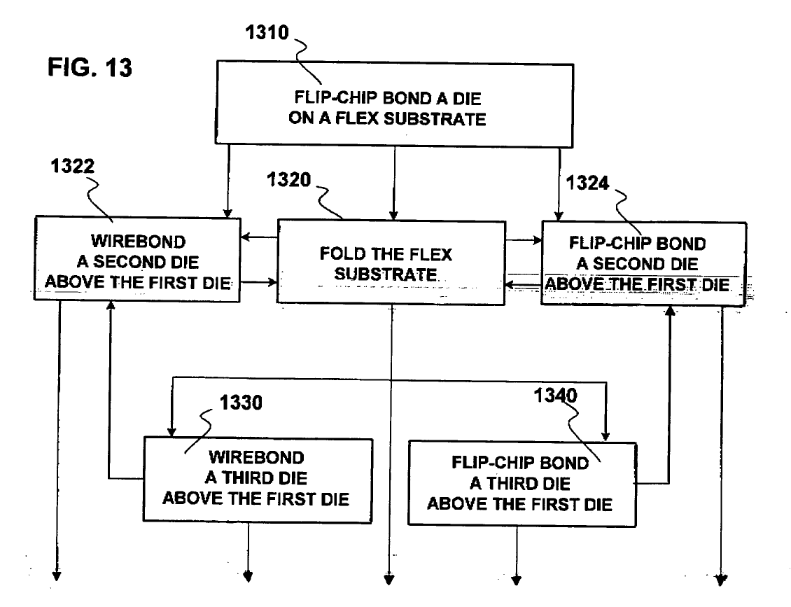

FIG. 13 is a process flow diagram according to various embodiments. In FIG. 13, a process 1300 includes flip-chip bonding a die to a flex substrate.

At 1310, the process includes flip-chip bonding a die to a flex substrate. By way of non-limiting example, the first die 110 in FIG. 1 is flip-chip bonded to the flex substrate 112. In an embodiment, the process terminates at 1310.

At 1320, a process embodiment continues after flip-chip bonding the die onto the flex substrate by first folding the flex substrate to produce a folded flex substrate. By way of non-limiting example, the first die 310 in FIG. 3 is enclosed in the flex substrate 312 by first folding the flex substrate 312. In an embodiment, the process terminates at 1320.

At 1322, a process embodiment includes first wirebonding a second die above the first die. By way of non-limiting example, the second die 524 in FIG. 5 is wirebonded above the first die 510. In an embodiment, the process terminates at 1322. In an embodiment, the process includes first wirebonding at 1322, followed by folding the flex substrate at 1320. By way of non-limiting example, the second die 624 in FIG. 6 is wirebonded above the first die 610, followed by folding the MFF mounting substrate 612 over the second die 624. In an embodiment, the process terminates after passing through 1322, followed by passing through 1320.

At 1324, a process embodiment includes flip-chip bonding a second die above the first die. By way of non-limiting example, the second die 724 in FIG. 7 is flip-chip bonded above the first die 710. In an embodiment, the process terminates at 1324. In an embodiment, the process includes first flip-chip bonding at 1324, followed by folding the flex substrate at 1320. By way of non-limiting example, the second die 1024 in FIG. 10 is flip-chip bonded above the first die 1010, followed by folding the MFF mounting substrate 1012 over the second die 1024. In an embodiment, the process terminates after passing through 1324, followed by passing through 1320.

At 1330, a process embodiment includes wirebonding a third die above the first die. This process can include any of the first and second bonding processes. In an embodiment, the process terminates at 1330.

At 1340, a process embodiment includes flip-chip bonding a third die above the first die. This process can include any of the first and second bonding processes. In an embodiment, the process terminates at 1340.

FIG. 14 is a depiction of a computing system according to an embodiment. One or more of the foregoing embodiments of a flip-chip bonded to a flex substrate may be utilized in a computing system, such as a computing system 1400 of FIG. 14. The computing system 1400 includes at least one processor (not pictured), which is enclosed in a microelectronic device package 1410, a data storage system 1412, at least one input device such as a keyboard 1414, and at least one output device such as a monitor 1416, for example. The computing system 1400 includes a processor that processes data signals, and may include, for example, a microprocessor, available from Intel Corporation. In addition to the keyboard 1414, the computing system 1400 can include another user input device such as a mouse 1418, for example. Similarly depending upon the complexity and type of computing system, the computing system 1400 can include a board 1420 for mounting at least one of the flip-chip mounted on a flex substrate for a microelectronic device package 1410, a data storage system 1412, or other components.

For purposes of this disclosure, a computing system 1400 embodying components in accordance with the claimed subject matter may include any system that utilizes a microelectronic device package, which may include, for example, a data storage device such as dynamic random access memory, polymer memory, flash memory, and phase-change memory. The microelectronic device package can also include a die that contains a digital signal processor (DSP), a micro controller, an application specific integrated circuit (ASIC), or a microprocessor.

Embodiments set forth in this disclosure can be applied to devices and apparatuses other than a traditional computer. For example, a die can be packaged with an embodiment of the flip-chip bonded to a flex substrate, and placed in a portable device such as a wireless communicator or a hand-held device such as a personal data assistant and the like. Another example is a die that can be packaged with an embodiment of the flip-chip bonded to a flex substrate and placed in a vehicle such as an automobile, a locomotive, a watercraft, an aircraft, or a spacecraft.

The Abstract is provided to comply with 37 C.F.R. §1.72(b) requiring an Abstract that will allow the reader to quickly ascertain the nature and gist of the technical disclosure. It is submitted with the understanding that it will not be used to interpret or limit the scope or meaning of the claims.

In the foregoing Detailed Description, various features are grouped together in a single embodiment for the purpose of streamlining the disclosure. This method of disclosure is not to be interpreted as reflecting an intention that the claimed embodiments of the invention require more features than are expressly recited in each claim. Rather, as the following claims reflect, inventive subject matter lies in less than all features of a single disclosed embodiment. Thus the following claims are hereby incorporated into the Detailed Description of Embodiments of the Invention, with each claim standing on its own as a separate preferred embodiment.

It will be readily understood to those skilled in the art that various other changes in the details, material, and arrangements of the parts and method stages which have been described and illustrated in order to explain the nature of this invention may be made without departing from the principles and scope of the invention as expressed in the subjoined claims.

What is claimed is:

1. An article comprising:
a first die, wherein the first die is a flip-chip disposed on a flex substrate.

2. The article of claim 1, wherein the flex substrate is selected from a single-layer flex substrate and a multi-layer flex substrate.

3. The article of claim 1, wherein the flex substrate is selected from a single-layer flex substrate and a multi-layer flex substrate, and wherein the flex substrate is selected from a planar-flex substrate and a folded-flex substrate.

4. The article of claim 1, further including a second die disposed above the first die.

5. The article of claim 1, further including a second die disposed above the first die, wherein the second die is wire-bonded to the flex substrate.

6. The article of claim 1, wherein the flex substrate is selected from a single-layer flex substrate and a multi-layer flex substrate, and wherein the flex substrate is selected from a planar-flex substrate and a folded-flex substrate, the article further including:
a second die disposed above the first die, wherein the second die is wire-bonded to the flex substrate.

7. The article of claim 1, wherein the flex substrate includes a first side and a second side, wherein the flex substrate is selected from a single-layer flex substrate and a multi-layer flex substrate, wherein the flex substrate is selected from a planar-flex substrate and a folded-flex substrate, the article further including:
a second die disposed above the first die, wherein the first die is disposed on the flex substrate first side, and wherein the second die is disposed on the flex substrate second side.

8. The article of claim 1, wherein the flex substrate includes a first side and a second side, wherein the flex substrate is selected from a single-layer flex substrate and a multi-layer flex substrate, wherein the flex substrate is selected from a planar-flex substrate and a folded-flex substrate, the article further including:
a second die disposed above the first die, wherein the first die is disposed on the flex substrate first side, wherein the second die is disposed on the flex substrate second side, and wherein the second die is bonded to the flex substrate second side by a configuration selected from wire-bonded and flip-chip bonded.

9. The article of claim 1, wherein the flex substrate includes a first side and a second side, wherein the flex substrate is a folded-flex substrate, the article further including:
a second die disposed above the first die, wherein the first die is disposed on the flex substrate first side, wherein the second die is disposed on the flex substrate first side; and
a third die disposed on the flex substrate second side and above the first die.

10. The article of claim 1, wherein the flex substrate includes a first side and a second side, wherein the flex substrate is a folded-flex substrate, the article further including:
a second die disposed above the first die, wherein the first die is disposed on the flex substrate first side, wherein the second die is disposed on the flex substrate first side; and
a third die disposed on the flex substrate second side and above the first die, wherein at least one of the second die and the third die is wire-bonded to the flex substrate.

11. The article of claim 1, wherein the flex substrate includes a first side and a second side, wherein the flex substrate is a folded-flex substrate, the article further including:
a plurality of second dice disposed above the first die, wherein the first die is disposed on the flex substrate first side, wherein the plurality of second dice is disposed on the flex substrate second side.

12. The article of claim 1, wherein the flex substrate includes a first side and a second side, wherein the flex substrate is a folded-flex substrate, the article further including:
a plurality of second dice disposed above the first die, wherein the first die is disposed on the flex substrate first side, wherein the plurality of second dice is disposed on the flex substrate second side; and
a third die disposed above the first die and below the plurality of second dice, wherein the third die is bonded to the flex substrate first side, and wherein the third die is bonded to the flex substrate first side by a configuration selected from wire-bond bonded and flip-chip bonded.

13. An article comprising:
a first die including an active surface and a backside surface, wherein the first die is flip-chip disposed on a rigid substrate; and
a second die disposed above the first die, wherein the second die is wire-bonded to the rigid substrate.

14. The article of claim 13, wherein the second die is selected from a memory device, a digital signal processor, a graphics processor, and a combination of at least two thereof.

15. The article of claim 13, wherein the second die is one of a plurality of dice.

16. A computing system comprising:
a first die, wherein the first die is flip-chip disposed on a flex substrate; and
at least one of an input device and an output device coupled to the first die.

17. The computing system of claim 16, wherein the computing system is disposed in one of a computer, a wireless communicator, a hand-held device, an automobile, a locomotive, an aircraft, a watercraft, and a spacecraft.

18. The computing system of claim 16, wherein the die is selected from a data storage device, a digital signal processor, a micro controller, an application specific integrated circuit, and a microprocessor.

19. The computing system of claim 16, wherein the die is disposed in a computer shell.

20. The computing system of claim 16, wherein the flex substrate is selected from a single-layer flex substrate and a multi-layer flex substrate.

21. The computing system of claim 16, wherein the flex substrate is selected from a single-layer flex substrate and a multi-layer flex substrate, and wherein the flex substrate is selected from a planar-flex substrate and a folded-flex substrate.

22. The computing system of claim 16, further including a second die disposed above the first die.

23. The computing system of claim 16, further including a second die disposed above the first die, wherein the second die is wire-bonded to the flex substrate.

24. The computing system of claim 16, further including:
a second die disposed above the first die; and
at least one third die disposed above the second die.

25. A process comprising:
flip-chip bonding a first die to a flex substrate.

26. The process of claim 25, further including:
wire-bonding a second die to the flex substrate, wherein the second die is disposed above the first die.

27. The process of claim 25, further including:
wire-bonding a second die to the flex substrate, wherein the second die is disposed above the first die, and wherein wire-bonding is carried out selected from forward wire-bonding and reverse wire-bonding.
